(19) United States
(12) Patent Application Publication
(10) Pub. No.: US 2014/0063744 A1
(43) Pub. Date: Mar. 6, 2014

(54) Vertically Stacked Power FETS and Synchronous Buck Converter Having Low On-Resistance

(71) Applicants: Osvaldo Jorge Lopez, Annandale, NJ (US); Jonathan A. Noquil, Bethlehem, PA (US); Juan Alejandro Herbsommer, Allen, TX (US)

(72) Inventors: Osvaldo Jorge Lopez, Annandale, NJ (US); Jonathan A. Noquil, Bethlehem, PA (US); Juan Alejandro Herbsommer, Allen, TX (US)

(73) Assignee: TEXAS INSTRUMENTS INCORPORATED, Dallas, TX (US)

(21) Appl. No.: 13/603,905

(22) Filed: Sep. 5, 2012

(51) Int. Cl. H05K 7/20; H01L 25/07; H05K 1/18

(52) U.S. Cl. 361/719; 361/783; 257/368; 257/E25.014

(57) ABSTRACT

A power FET (100) comprising a leadframe including a pad (110), a first lead (111), and a second lead (112); a first metal clip (150) including a plate (150a), an extension (150b) and a ridge (150c), the plate and extension spaced from the leadframe pad and the ridge connected to the pad; a vertically assembled stack of FET chips in the space between the plate and the pad, the stack including a first n-channel FET chip (120) having the drain terminal on one surface and the source and gate terminals on the opposite surface, the drain terminal attached to the pad, the source terminal attached to a second clip (140) tied to the first lead; and a second n-channel FET chip (130) having the source terminal on one surface and the drain and gate terminals on the opposite surface, the source terminal attached to the second clip, its drain terminal attached to the first clip; wherein the drain-source on-resistance of the FET stack is smaller than the on-resistance of the first FET chip and of the second FET chip.

### FIELD OF THE INVENTION

The present invention is related in general to the field of semiconductor devices and processes, and more specifically to the structure and fabrication method of a small-size, three-dimensional field-effect transistors having ultra-low source-drain on-resistance.

### DESCRIPTION OF RELATED ART

Among the popular families of power switching devices are the DC-DC power supply circuits, especially the category of Switched Mode Power Supply circuits. Particularly suitable for the emerging power delivery requirements are the synchronous Buck converters, or Power Blocks, with two power MOS field effect transistors (FETs) connected in series and coupled together by a common switch node. In the Power Block, the control FET chip, also called the high-side switch, is connected between the supply voltage V_{IN} and the LC output filter, and the synchronous (sync) FET chip, also called the low side switch, is connected between the LC output filter and ground potential.

The gates of the control FET chip and the sync FET chip are connected to a semiconductor chip including an integrated circuit (IC) acting as the driver of the converter, and the driver, in turn, is connected to a controller IC. The assembly is often referred to as Power Stage. Preferably, both driver and controller ICs are integrated on a single chip, which is also connected to ground potential.

For many of today's power switching devices, the chips of the power MOSFETs and the chip of the driver and controller IC are assembled horizontally side-by-side as individual components. Each chip is typically attached to a rectangular or square-shaped pad of a metallic leadframe; the pad is surrounded by leads as output terminals. The leads are commonly shaped without cantilever extensions, and arranged in the manner of Quad Flat No-Lead (QFN) or Small Outline No-Lead (SON) devices. The electrical connections from the chips to the leads may be provided by bonding wires, which introduce, due to their lengths and resistances, significant parasitic inductance into the power circuit. In some recently introduced advanced assemblies, clips substitute for many connecting wires. These clips are wide and introduce minimum parasitic inductance. Each assembly is typically packaged in a plastic encapsulation, and the packaged components are employed as discrete building blocks for board assembly of power supply systems.

For many applications it is desirable to have a small on-resistance of the converter and thus a small on-resistance of each discrete FET. In order to reduce the on-resistance of parallel operating FETs, efforts by the semiconductor industry focus, for instance, on minimizing the effective resistance of discrete MOS FETs by positioning the MOS fingers closer together; this can be achieved by reducing the pitch between MOS fingers employing trenches in the semiconductor material.

When the application allows sufficient assembly area on a board, it is well known to reduce the on-resistance Rₒₙ of a chip by placing two identical chips side by side and connecting them electrically in parallel. If the connecting traces of the board would add no parasitic resistances, the on-resistance of the two chips in parallel would be ½ Rₒₙ. In a typical example, a conventional MOS FET is made as a chip of a semiconductor n-type starting material, usually positioned at the bottom of the chip, operating as the drain contact enforced as an n+ substrate, and solderable. An epitaxial p-type body, formed in the n-type semiconductor, is contacted as the source of the FET. The metallic contact to the source is positioned on the top side of the chip and also solderable. The gate, positioned above the p-type region, operates by forming n-channels in the “on” stage. The metallic contact to the gate is also positioned on the top side of the chip (and usually contacted by ball-bonded wire). The source-to-drain resistance of the FET in the on-stage is called on-resistance Rₒₙ.

When a small on-resistance is required, it is common practice in known technology to reduce the on-resistance by assembling two FET chips in parallel side-by-side in drain-down position at close proximity on a horizontal substrate such as a printed circuit board. The electrical connections of the board are typically formed by copper traces on and in the substrate. These substrate traces add small parasitic resistances to the on-resistance of the FETs in parallel position. Further parasitic resistances are added to the on-resistance by clips and leadframes, and by the contact resistances of the connections.

### SUMMARY OF THE INVENTION

Applications of power electronics such as power converters, power blocks and power stages in markets as diverse as handheld, laptop, automotive, and medical products drive an ongoing demand for increased power density and reduced power dissipation. Applicants realized that these demands call for better efficiency and smaller packages. However, approaches to improve efficiency in DC/DC converters, which focus on reducing conduction losses in MOS FETs through lower drain-to-source on-resistance R_{DSon} and lowering switching losses through low frequency operation, are on a point of diminishing returns, since low R_{DSon} devices have large parasitic capacitances that do not facilitate the high-frequency operation required to improve power density.

Applicants solved the problem of creating low on-resistance for power FETs, Power Blocks, and Power Stages, while simultaneously minimizing PCB area, when they discovered a methodology of stacking vertically a source-down n-channel FET on top of a drain-down n-channel FET using a combination of clips that tie the necessary electrodes together. As a result, the two FETs are vertically connected in parallel, while restricting the consumed printed circuit board (PCB) area to the area of a discrete package for a single chip. The stacked chips further provide the external terminal designations of a single FET device, and avoid altogether the parasitic impedances of PCB traces. In addition, the stacked power FETs offer thermal and electrical efficiencies close to the theoretical maximum, and permit direct implementation into PCBs without the headache of first modifying a footprint.

In an exemplary preferred embodiment, a power field-effect transistor (FET) uses a QFN/SON-type leadframe, which includes a flat plate, a first coplanar flat strip, and a second coplanar flat strip. Vertically assembled on the leadframe is a stack of a first n-channel FET chip, which has the source terminal on one surface and the drain and gate terminals on the opposite surface, and also has a first on-resistance, and a second n-channel FET chip, which has the drain terminal on one surface and the source and gate terminals on the opposite surface, and also has a second on-resistance. For the stacking, the first chip has its drain terminal attached to the plate, its source terminal attached to a first clip tied to the first strip, and its gate terminal connected to the second strip; the second chip has its source terminal attached to the first clip, its drain terminal attached to a second clip tied to the plate, and its gate terminal connected to the second strip. The stack may be encapsulated in molding compound to complete a power field-effect transistor, where a surface of each leadframe piece remains un-encapsulated. The leadframe plate is then the drain terminal of the FET, the first strip the source terminal, and the second strip the gate terminal.

The power FET structure allows an electrical current to enter the FET at the source terminal, to split into two branches flowing in parallel through the first and second chips, and then to exit the FET through the drain terminal. The drain-to-source on-resistance of the stacked FET is thus smaller than the on-resistance of the first FET chip and smaller than the on-resistance of the second FET chip. If the first chip and the second chip are identical (area and on-resistance), the on-resistance of the stack is half of the on-resistance of a discrete chip, since there are no board traces with parasitic resistances.

Another preferred embodiment is a Half Bridge (also called a Power Block) formed by coupling a first low on-resistance power FET stack with a second low on-resistance power FET stack (and an inductor). The second FET has its source connected to an input voltage and its drain coupled to the source of the first FET. The drain of the first FET is at ground potential. The gate of the second FET and the gate of the first FET are operated by a gate driver (an integrated circuit IC), which in turn is regulated by a controller (preferably included in the IC). The common connection between the first source and the second drain operates as the switch.

### BRIEF DESCRIPTION OF THE DRAWINGS

FIGS. 1A, 1B, and 1C show a packaged power field-effect transistor including two FET chips vertically assembled on a leadframe.

FIG. 1A is a perspective view of the assembled power FET stack with the package assumed to be transparent.

FIG. 1B illustrates a top view of the assembled FET stack.

FIG. 1C depicts a cross section of the assembled FET stack, illustrating how the vertically stacked chips allow an electrical current to flow through the stack in parallel branches so that the total drain-to-source on-resistance is about half the on-resistance of each FET chip.

FIG. 2A is a top view of a synchronous Buck converter (Power Block) formed by placing a control module of two stacked chips adjacent to a sync module of two stacked chips.

FIG. 2B shows a cross section of the assembled synchronous Buck converter.

FIG. 3A illustrates a top view of a Power Block analogous to the Power Block in FIG. 2A with an un-encapsulated top for improved thermal characteristics.

FIG. 3B is a cross section of the double-cool Power Block of FIG. 3A.

FIG. 4A depicts a top view of a synchronous Buck converter (Power Stage) with capacitor and IC chip for gate driver and control assembled in the package.

FIG. 4B is a cross section of the Power Stage of FIG. 4A.

### DETAILED DESCRIPTION OF THE PREFERRED EMBODIMENTS

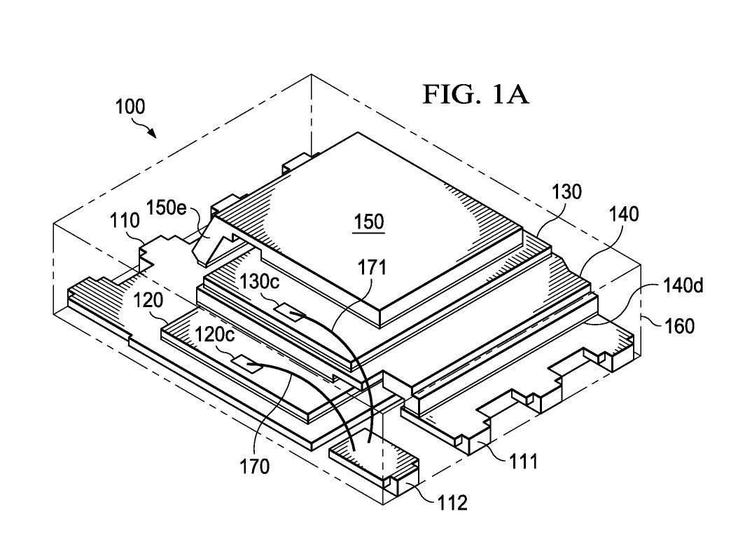

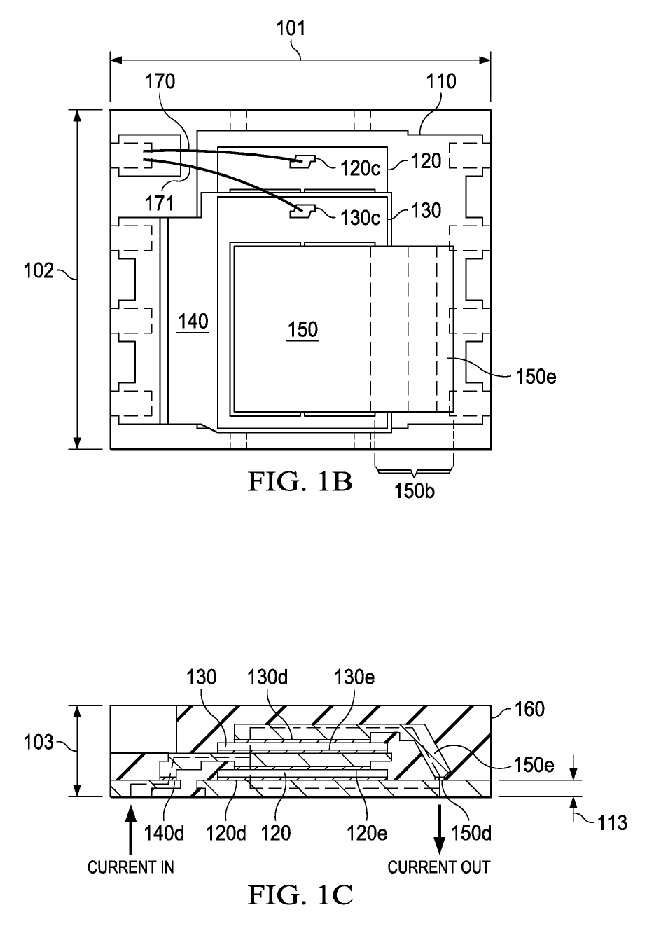

FIGS. 1A, 1B, and 1C display various views of an embodiment of an exemplary switch including a power field-effect transistor (FET), generally designated 100. Power FET 100 is assembled on a leadframe as a vertical stack of two FET chips according to the invention and encapsulated in packaging material 160 such as a molding compound; the encapsulation is assumed transparent in FIGS. 1A and 1B. The exemplary power FET of FIGS. 1A, 1B, and 1C has a length 101 of 6.0 mm, a width 102 of 5.0 mm, and a height 103 of 1.5 mm.

The leadframe includes a flat pad 110, a first flat lead 111, which is coplanar with pad 110, and a second flat lead 112, which is also coplanar with pad 110. The leadframe portions 110, 111, and 112 are preferably stamped or etched from a metallic starting sheet, hence the coplanarity. The leadframe is preferably made of copper or copper alloy; other alternatives include iron-nickel alloys (such as Alloy 42), aluminum, and Kovar™. Leadframe thickness 113 is preferably between about 0.15 and 0.25 mm, but may be thinner or thicker. In order to facilitate the attachment of a semiconductor chip and also the attachment to an external part, it may be advantageous to provide the leadframe surfaces with a solderable metallurgical preparation, such as a layer of tin or nickel.

The first n-channel FET chip of power FET 100 is designated 120 in FIGS. 1A, 1B, and 1C. First chip 120 has its drain terminal (an n+ substrate on the n-type starting material) facing leadframe plate 110. The source terminal and the gate terminal of chip 120 are on the chip surface opposite plate 110; the gate terminal is designated 120c. An exemplary chip 120 may have a length of 3.5 mm, a width of 2.84 mm, resulting in an area of about 10 mm², and a thickness of about 0.1 mm; the source terminal may be designed as two pads. Alternatively, chip 120 may have a larger or smaller area. The n-type starting material of chip 120 has an n+ substrate operating as the FET drain terminal; preferably, the n+ substrate has a solderable metallic surface. An epitaxial p-type body is tied to the source.

The source terminal is positioned on the chip surface opposite the drain terminal; preferably, the source terminal metal is solderable. In contrast, the gate terminal 120c is preferably connected by bonding wire 170 to second leadframe strip 112. In the “on” regime of chip 120, the gate operates by forming an n-channel in the p-region between source and drain. In the on-regime, the channel determines the source-to-drain on-resistance Rₒₙ₁ of chip 120.

The drain terminal of first FET chip 120 is attached, preferably by solder layer 120d, to leadframe pad 110. Alternatively, a layer of conductive adhesive, z-axis conductor, carbon tubes, or graphene material may be used. The source terminal of first FET chip 120 is attached, preferably by solder layer 120e, to a metal clip 140 (herein referred to as second clip; preferably made of copper). Like the other interconnecting metal clip of transistor 100, second clip 140 has a wide design and a thickness of about 0.2 to 0.3 mm, so that it introduces only minimal parasitic resistance and inductance. Clip 140 is tied, preferably by solder layer 140d, to first leadframe lead 111.

The second n-channel FET chip of power FET 100 is designated 130 in FIGS. 1A, 1B, and 1C. Second chip 130 has its source terminal (a p+ substrate with p-epitaxial material implanted for n+ conductivity) facing first clip 140. The source terminal of chip 130 is attached to second clip 140 by solder layer 130e. Since second clip 140 is tied to first lead 111, the first lead 111 operates as the common source terminal of power transistor 100. The drain terminal and the gate terminal of chip 130 are on the chip surface opposite clip 140; the gate terminal is designated 130c. An exemplary chip 130 may have a length of 3.5 mm, a width of 2.84 mm, resulting in an area of about 10 mm², and a thickness of about 0.1 mm; the drain terminal may be designed as two pads. Alternatively, chip 130 may have a larger or smaller area. More preferably, second chip 130 has the same area as first chip 120. Preferably, the p+ substrate as the source contact has a solderable metallic surface.

The drain terminal is positioned on the chip surface opposite the source terminal; preferably, the drain terminal metal is solderable. In contrast, the gate terminal 130c is preferably connected by bonding wire 171 to second leadframe lead 112. Since bonding wire 170 is also tied to second lead 112, the second lead 112 operates as the common gate terminal of power transistor 100. In the on-regime of chip 130, the gate operates by forming an n-channel in the p-region between source and drain. In the on-regime, the channel determines the source-to-drain on-resistance Rₒₙ₂ of chip 130.

As stated, the source terminal of second FET chip 130 is attached by solder layer 130e to second clip 140. The drain terminal of second FET chip 130 is attached, preferably by solder layer 130d, to a metal clip 150 (herein referred to as first clip; preferably made of copper). Like the other interconnecting metal clip of transistor 100, second clip 150 has a wide design and a thickness of about 0.2 to 0.3 mm so that it introduces only minimal parasitic resistance and inductance. Clip 150 is tied, preferably by solder layer 150d, to leadframe plate 110. Since first clip 150 is tied to leadframe plate 110, the pad 110 operates as the common drain terminal of power transistor 100.

As described above in conjunction with FIGS. 1A, 1B, and 1C, exemplary power transistor 100 includes the two FET chips 120 and 130 vertically stacked and electrically connected “in parallel” by means of a leadframe and two clips. It is well known that the total on-resistance Rₒₙ of two field-effect transistors with drain-to-source on-resistances Rₒₙ₁ and Rₒₙ₂ can be made smaller than the smallest on-resistance of each individual transistor, when the FETs are electrically connected “in parallel”. For negligible parasitic resistances of the interconnections, Rₒₙ is obtained by

1/Rₒₙ=1/Rₒₙ₁+1/Rₒₙ₂.

For two FETs with equal on-resistance, Rₒₙ₁=Rₒₙ₂, parallel positioning of the transistors allows to reduce the total on-resistance Rₒₙ in half: Rₒₙ=½Rₒₙ₁. The on-resistance depends on the chip size of the FET. As an example, for an FET with a chip area of 5 mm², the on-resistance may be about 2.0 mΩ. Two of these FETs of equal area interconnected in parallel have a total on-resistance Rₒₙ of about 1.0 mΩ, when the parasitic resistances of the interconnections can be neglected. Otherwise, the on-resistance can realistically be expected to be about 1.1 mΩ.

An analogous relationship holds for parallel arrangement of on-impedances. When a FET with on-impedance Zₒₙ₁ is connected in parallel with a FET with on-impedance Zₒₙ₂ and further the phase difference of the current relative to the voltage is the same in both transistors, φ₁=φ₂, the total on-impedance Zₒₙ is given by

1/Zₒₙ=1/Zₒₙ₁+1/Zₒₙ₂.

If the phase difference between current and voltage is not same in both transistors, φ₁φ₂, the following relationship holds:

1/Zₒₙ=[(1/Zₒₙ₁)²+(1/Zₒₙ₂)²+2/(Zₒₙ₁·Zₒₙ₂)·cos(φ₁−φ₂)]^{1/2}.

The reciprocal value 1/Zₒₙ of the impedance is for parallel connection usually smaller than the sum 1/Zₒₙ₁+Zₒₙ₂ of the reciprocal discrete impedances. For individual devices, the effort to create low on-impedance has to be concerned with each and every additional fraction of an ohm, so even small parasitic impedances have to be counted, especially the interconnecting traces of an assembly board.

It is a technical advantage of the vertical assembly of chips 120 and 130 on a leadframe that the vertical assembly allows an electrical current to flow through the stack in parallel branches with negligible parasitic resistances and inductances (see FIG. 1C). In contrast, in known art substantial parasitics derive from the conductive traces on assembly boards conventionally used for side-by-side assembly of the chips. The current branches flowing in parallel through a stack of two vertically assembled chips with about equal on-resistance of an individual chip (see FIG. 1C) encounter a total drain-to-source on-resistance of only half the value of the on-resistance of each discrete chip. The stacking of two FET chips, as illustrated in FIGS. 1A, 1B, and 1C, is particularly easy when both chips have the same area, for example 5 mm² or 10 mm².

The above considerations and vertically stacked assembly remain valid, when in both FET chips the order of source and drain is reversed. In an embodiment with these chip polarities, the leadframe plate 110 represents the common source terminal of the stacked power FET and the first leadframe strip 111 the common drain terminal, while the second leadframe strip 112 remains the common gate terminal.

Another embodiment of the invention is a DC-DC power supply device belonging to the power switching devices, wherein two power MOS FETs are connected in series and coupled together by a common switch node. A device of this family is commonly known as synchronous Buck converter, sometimes referred to as Half Bridge or Power Block. In the Buck converter, the control FET module, also called the high side switch, is connected between the supply voltage Vᵢₙ and the LC output filter, and the synchronous (sync) FET module, also called the low side switch, is connected between the LC output filter and ground potential. When the device further includes a gate driver circuit and a controller circuit, it is sometimes referred to as Power Stage. In the embodiment, each power MOS FET of the converter is a module with minimized on-resistance due to parallel connection of two FET chips in vertically stacked configurations.

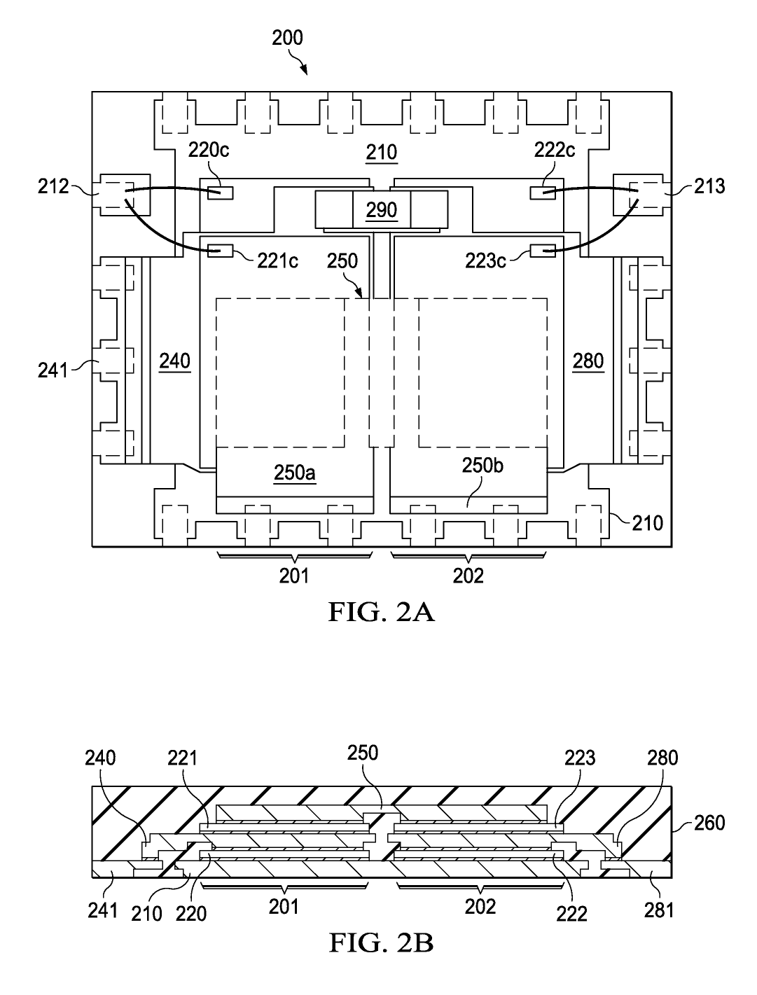

An exemplary synchronous Buck converter or Power Block according to the invention is illustrated in FIGS. 2A and 2B to display the construction of a device generally designated 200. In the top view of FIG. 2A, the encapsulation 260, which is preferably a black-colored molding compound, is assumed to be transparent for clarity purposes. Using chips of similar size as in FIG. 1B, the device length in FIG. 2A is 8.5 mm and the device width 6.5 mm. These dimensions can be reduced when smaller chips are used. Device 200 includes a leadframe and a synchronous Buck converter assembled on the leadframe. The control FET module 201 of the converter is placed side-by-side and in close proximity to the sync FET module 202 of the converter; both modules are conductively attached to leadframe pad 210. The preferred attachment material is a layer of solder; alternatively, a layer of conductive adhesive, z-axis conductor, carbon tubes, or graphene material may be used. Leadframe pad 210 is electrically the switch node terminal of the Buck converter.

The leadframe further includes a lead 241 as input terminal Vᵢₙ, a lead 280 as ground terminal, a lead 212 as gate terminal of the control module 201, and a lead 213 as gate terminal of the sync module 202.

The synchronous buck converter includes the control module 201 and the sync module 202. Control module 201 comprises a first n-channel FET chip 220 and a second n-channel FET chip 221, which preferably have equal areas. First chip 220 has its source on one surface and its drain and gate on the opposite surface. As illustrated in the exemplary embodiment of FIG. 2B, chip 220 is aligned so that the source of chip 220 faces pad 210 of the leadframe. First chip 220 further has a first drain-to-source on-resistance Rₒₙ₁. As depicted in FIG. 2B, second chip 221 preferably has the same area as first chip 220. Second chip 221 has its drain on one surface and its source and gate on the opposite surface. As illustrated in the exemplary embodiment of FIG. 2B, chip 221 is aligned so that the drain of chip 221 faces in the direction to pad 210 of the leadframe. Second chip 221 further has a second drain-to-source on-resistance Rₒₙ₂.

First chip 220 and second chip 221 are assembled as a stack vertically on pad 210. First chip 220 has its source attached (preferably by a solder layer) to pad 210, and its drain attached to a clip 240 (herein referred to as second clip), which is the common drain terminal of the converter and tied to lead 241 as input terminal Vᵢₙ. Second clip 240 preferably has thickness of about 0.2 to 0.3 mm and a wide design suitable for high-current connection and minimum resistance and inductance. Second chip 221 has its drain attached to second clip 240, and its source attached to a clip 250 (herein referred to as first clip), which is tied to pad 210.

Due to this connection, first and second chips are electrically connected in parallel. Consequently, the drain-to-source on-resistance of the control module R_{on-control} is smaller than the smaller of the drain-to-source on-resistances Rₒₙ₁ and Rₒₙ₂ of each FET chip 220 and 221.

The shape of first clip 250 for its connection to pad 210 can be inferred to from FIG. 2A; the shape of clip 250 is similar to the shape of clip 150 in FIG. 1A. Clip 250 includes a plate 250a (top view in FIG. 2A and cross section in FIG. 2B), an extension 250b forming an obtuse angle with the plate, and a ridge. Plate 250a and extension 250b are spaced from pad 210; the ridge is connected to pad 210, for instance by a solder layer. In the space formed by the plate and the extension, the control and the sync modules of the Buck converter can be accommodated. Due to its attachment to pad 210, first clip 250 has electrically the potential of the switch node.

Sync module 202 comprises a third n-channel FET chip 222 and a fourth n-channel FET chip 223, which preferably have equal areas. More preferably, all four chips 220, 221, 222 and 223 have equal areas. Third chip 222 has its drain on one surface and its source and gate on the opposite surface. As illustrated in the exemplary embodiment of FIG. 2B, chip 222 is aligned so that the drain of chip 222 faces pad 210 of the leadframe. Third chip 222 further has a third drain-to-source on-resistance Rₒₙ₃. As depicted in FIG. 2B, fourth chip 223 preferably has the same area as third chip 222. Fourth chip 223 has its source on one surface and its drain and gate on the opposite surface. As illustrated in the exemplary embodiment of FIG. 2B, chip 223 is aligned so that the source of chip 223 faces in the direction to pad 210 of the leadframe. Fourth chip 223 further has a fourth drain-to-source on-resistance Rₒₙ₄.

Third chip 222 and fourth chip 2213 are assembled as a stack vertically on pad 210. Third chip 222 has its drain attached (preferably by a solder layer) to pad 210, and its source attached to a clip 280 (herein referred to as third clip), which is the common source of the converter and tied to lead 281 as ground terminal (PGND). Third clip 280 preferably has thickness of about 0.2 to 0.3 mm and a wide design suitable for high-current connection and minimum resistance and inductance. Fourth chip 223 has its source attached to third clip 280, and its source attached to first clip 250, which is tied to pad 210.

Due to this connection, third and fourth chips are electrically connected in parallel. Consequently, the drain-to-source on-resistance of the sync module R_{on-sync} is smaller than the smaller of the drain-to-source on-resistances Rₒₙ₃ and Rₒₙ₄ of each FET chip 222 and 223.

It should be pointed out that since the on-resistance is inversely proportional to the active chip area, the duty cycle of the synchronous Buck converter determines the ratio of the active areas needed for the control module relative to the sync module. Frequently, the anticipated duty cycle is low most of the time (<0.5); the control module is off and not conducting, while the sync module is conducting most of the cycle time. To reduce conduction losses of the Buck converter, the sync module needs an active area equal to or larger than the active area of control module. Consequently, the sync module preferably has a physical area equal to or larger than the physical area of the control module.

The gate 220c of first FET chip 220 and gate 221c of second FET chip 221 are connected by bonding wires to lead 212 as the gate terminal of control module 201; gate 222c of third FET chip 222 and gate 223c of fourth FET chip 223 are connected by bonding wires to lead 213 as the gate terminal of sync module 202.

It is an additional technical advantage of the spacial arrangements depicted in FIG. 2A that at least one capacitor can be positioned so that it bridges the gap between second clip 240 and third clip 280. In this fashion, capacitor 290 becomes an integral part of the synchronous Buck converter.

The synchronous Buck converter illustrated in exemplary FIGS. 2A and 2B exhibits excellent electrical performance compared to the characteristics achievable using conventional technology with higher on-resistances and parasitics. The converter can thus operate at higher frequencies. The methodology to achieve high performance and efficiency based on the invention can be summarized as follows:

The drain-to-source on-resistance of both the control module and the sync module are minimized due to connecting in parallel two FET chips of substantially equal conductive characteristics for each module.

The stacked configuration of FIGS. 2A and 2B virtually eliminates parasitic resistances and inductances between the FET chips resulting from wire interconnections and board traces. The stacked configuration furthermore saves board real estate.

High-current connections benefit from using thick copper clips due to reduced conduction losses and parasitics associated with Vᵢₙ and V_{switch} connections, when compared with wire-bonded solutions.

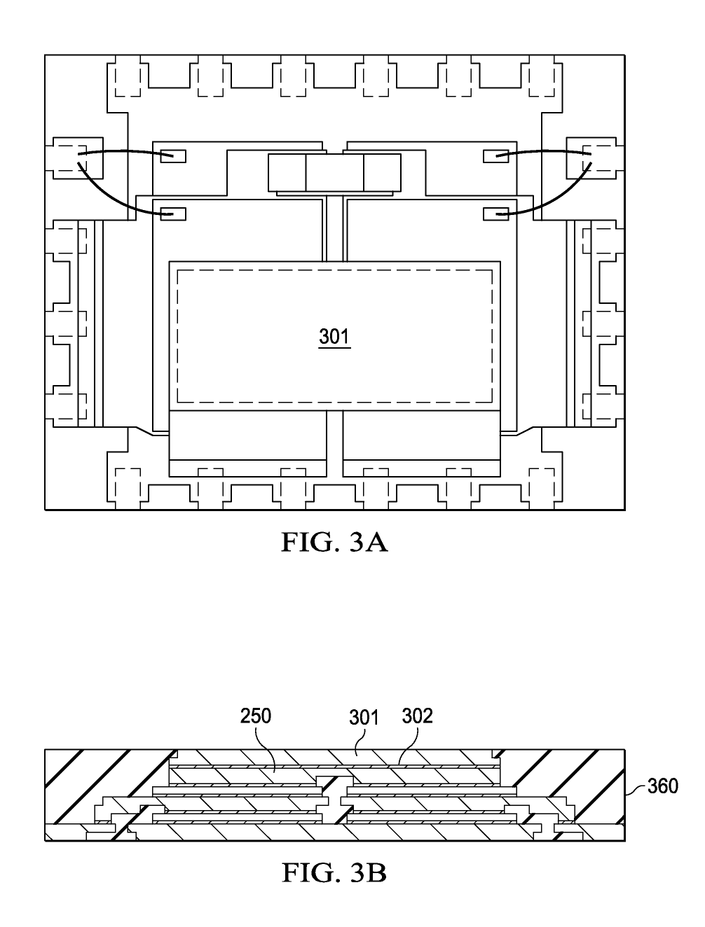

FIGS. 3A and 3B show another embodiment, which enhances the thermal characteristics of the synchronous Buck converter. A metallic plate 301, for example made of copper, is attached (for instance by solder layer 302) to first clip 250 and remains un-encapsulated, when the chips and clips of the converter are packaged in an encapsulation material 360. Plate 301 thus becomes not only a heat spreader, but also a heat sink. It may be further attached to an external heat sink, for instance with a metallic fin structure. The low thermal resistance of the converter is thus supplemented and enhanced by improved thermal conductance external heat sinks.

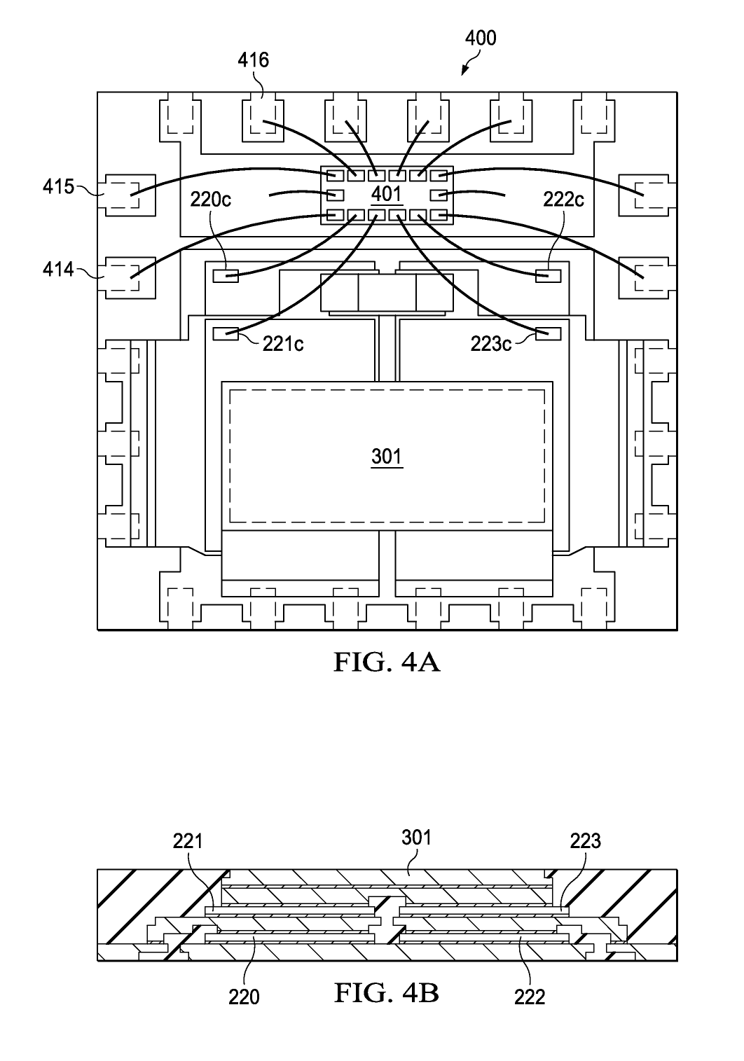

FIGS. 4A and 4B illustrate another embodiment, which incorporates an IC circuit 401 as gate driver and controller into the package of a synchronous Buck converter generally designated 400. An integrated converter as shown in FIGS. 4A and 4B is often referred to a Power Stage. Gate driver 401 is connected by bonding wires with the gates 220c, 221c, 222c, and 223c of FET chips 220, 221, 222, and 223 respectively, and by additional bonding wires to an increased number of separate leadframe leads such as designations 414, 415, 416, and so on. The area of IC 401 and the enlarged number of leads may require a somewhat enlarged size of the package of converter 400, approaching a more square-shaped package (8.5 mm by 8.0 mm), but the integrated converter 400 may be reduced when smaller chips are employed.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies not only to field effect transistors, but also to other suitable power transistors.

As another example, the high current capability of the power supply module can be further extended, and the efficiency further enhanced, by leaving the top surface of the second clip un-encapsulated so that the second clip can be connected to a heat sink, preferably by soldering. In this configuration, the module can dissipate its heat from both surfaces to heat sinks.

It is therefore intended that the appended claims encompass any such modifications or embodiments.

1. A stacked field-effect transistor (FET) package comprising:
a leadframe including a pad, a first lead, and a second lead;
a first metal clip including a plate, an extension and a ridge, the plate and extension spaced from the leadframe pad and the ridge connected to the pad;
a vertically assembled stack of FET chips in the space between the plate and the pad, the stack including:
a first n-channel FET chip having the drain terminal on one surface and the source and gate terminals on the opposite surface, the drain terminal attached to the pad, the source terminal attached to a second clip tied to the first lead, and the gate terminal connected to the second lead by a bonding wire, the first chip having a first drain-source on-resistance; and
a second n-channel FET chip having the source terminal on one surface and the drain and gate terminals on the opposite surface, the source terminal attached to the second clip, the drain terminal attached to the first clip, and the gate terminal connected to the second lead by a bonding wire, the second chip having a second drain-source on-resistance,
wherein a drain-source on-resistance of the vertically assembled stacked FET chips is smaller than the first drain-source on-resistance and the second drain-source on-resistance.

2. The stacked FET package of claim 1 wherein the first chip and the second chip have the same area.

3. The stacked FET package of claim 1 further including a molding compound encapsulating the chips and the clips.

4. The stacked FET package of claim 3, wherein the molding compound leaves one surface of the second clip un-encapsulated.

5. The stacked FET package of claim 4 further including a heat sink attached to the un-encapsulated surface of the second clip.

6. (canceled)

7. A stacked field-effect transistor (FET) package comprising:
a leadframe including a pad, a first lead and a second lead;
a first n-channel FET chip having the drain terminal on one surface and the source and gate terminals on the opposite surface, the first chip having a first on-resistance;
a second n-channel FET chip having the source terminal on one surface and the drain and gate terminals on the opposite surface, the second chip having a second on-resistance;
the first chip and the second chip assembled as a stack vertically on the pad, wherein the first chip having its drain terminal attached to the pad, its source terminal attached to a second clip tied to the first lead, and its gate terminal connected to the second lead by a bonding wire; and
the second chip having its source terminal attached to the second clip, its drain terminal attached to a first clip tied to the pad, and its gate terminal connected to the second lead by a bonding wire,
wherein the on-resistance of the vertically assembled stacked FET chips is smaller than the first on-resistance and the second on-resistance.

8. The stacked FET package of claim 7 wherein the first chip and the second chip have the same area.

9. The stacked FET package of claim 7 further including a molding compound encapsulating the chips and the clips.

10. A stacked field-effect transistor (FET) package comprising:
a leadframe including a pad, a first lead and a second lead;
a first n-channel FET chip having the source terminal on one surface and the drain and gate terminals on the opposite surface, the first chip having a first on-resistance;
a second n-channel FET chip having the drain terminal on one surface and the source and gate terminals on the opposite surface, the second chip having a second on-resistance;
the first and the second chips assembled as a stack vertically on the pad;
the first chip having its source terminal attached to the pad, its drain terminal attached to a second clip tied to the first lead, and its gate terminal connected to the second lead by a bonding wire; and
the second chip having its drain terminal attached to the second clip, its source terminal attached to a first clip tied to the pad, and its gate terminal connected to the second lead by a bonding wire,
wherein the on-resistance of the stacked FET chips is smaller than the first on-resistance and the second on-resistance.

11. A power supply device comprising:
a leadframe including a pad as switch node terminal, a lead as input terminal, a lead as ground terminal, a lead as gate terminal of the control module, and a lead as gate terminal of the sync module; and
a synchronous buck converter including:
a control module comprising a first and a second n-channel FET chip; the first chip having its source on one surface and its drain and gate on the opposite surface, and having a first on-resistance; the second chip having its drain on one surface and its source and gate on the opposite surface, and having a second on-resistance;
the first and the second chip assembled as a stack vertically on the pad, wherein the first chip having its source attached to the pad, and its drain attached to a second clip tied to the input lead; and the second chip having its drain attached to the second clip, and its source attached to a first clip tied to the pad;
wherein the on-resistance of the stacked control module is smaller than the on-resistance of the first and the second FET chip; and
a sync module comprising a third and a fourth n-channel FET chip; the third chip having its drain on one surface and its source and gate on the opposite surface, and having a third on-resistance; the fourth chip having its source on one surface and its drain and gate on the opposite surface, and having a fourth on-resistance;
the third and the fourth chip assembled as a stack vertically on the pad, wherein the third chip having its drain attached to the pad, and its source attached to a third clip tied to the ground lead; and the fourth chip having its source attached to the third clip, and its drain attached to the first clip tied to the pad;
wherein the on-resistance of the stacked sync module is smaller than the on-resistance of the third and the fourth FET chip.

12. The power supply device of claim 11, wherein the first, the second, the third, and the fourth chip have the same area.

13. The power supply device of claim 11 further including a packaging compound encapsulating the chips and the clips.

14. The power supply device of claim 13 wherein the packaging compound leaves one surface of the third clip un-encapsulated.

15. The power supply device of claim 14 further including a heat sink attached to the un-encapsulated surface of the third clip.

16. The power supply device of claim 11 further including at least one capacitor attached to the second and the third clip.

17. The power supply device of claim 11 further including a chip operable as gate driver and controller, the chip attached to the leadframe pad.

18. A power supply device comprising:
a metal leadframe including a pad operable as the switch node of the device, a lead tied to input voltage, and a lead tied to ground potential;
a first metal clip including a plate, an extension and a ridge, the plate and extension spaced from the leadframe pad and the ridge connected to the pad, wherein the first clip is at switch node potential;
a synchronous Buck converter in the space between the plate and the pad, the converter including a control module and a sync module, both modules soldered onto the pad and onto the plate;
the control module including a drain-down second FET chip vertically stacked upon a source-down first FET chip, a second clip connecting the FET drains to the input lead and the first clip attached to the source of the first chip, wherein the chips being electrically connected in parallel and the drain-to-source on-resistance of the control module being smaller than the smaller of the drain-to-source on-resistances of the first and second FET chips; and
the sync module including a source-down fourth FET chip vertically stacked upon a drain-down third FET chip, a third clip connecting the FET sources to the ground lead, and the first clip attached to drain of the fourth chip, wherein the chips being electrically connected in parallel and the drain-to-source on-resistance of the sync module being smaller than the smaller of the drain-to-source on-resistances of the third and fourth FET chips.

19. The power supply device of claim 18 further including a packaging compound encapsulating the chips and the clips.

20. The power supply device of claim 19 wherein the packaging compound leaves one surface of the third clip un-encapsulated.

21. The power supply device of claim 20 further including a heat sink attached to the un-encapsulated surface of the third clip.

22. The power supply device of claim 18 further including at least one capacitor attached to the second and third clip.

23. The power supply device of claim 18 further including a chip operable as gate driver and controller, the chip attached to the leadframe pad.
